(19) United States
(12) Patent Application Publication
(10) Pub. No.: US 2025/0194130 A1
(43) Pub. Date: Jun. 12, 2025

(54) HIGH ELECTRON MOBILITY TRANSISTOR AND FABRICATING METHOD OF THE SAME

(71) Applicant: UNITED MICROELECTRONICS CORP., Hsin-Chu City (TW)

(72) Inventors: Zhi-Cheng Lee, Tainan City (TW); Chuang-Han Hsieh, Tainan City (TW); Huai-Tzu Chiang, Tainan City (TW); Kai-Lin Lee, Kinmen County (TW)

(73) Assignee: UNITED MICROELECTRONICS CORP., Hsin-Chu City (TW)

(21) Appl. No.: 19/062,037

(22) Filed: Feb. 25, 2025

Related U.S. Application Data
(62) Division of application No. 17/885,574, filed on Aug. 11, 2022.

(30) Foreign Application Priority Data
Jul. 13, 2022 (TW) 111126204

(51) Int. Cl. H10D 30/01; H10D 30/47; H10D 62/85

(52) U.S. Cl. CPC H10D 30/015; H10D 30/475; H10D 62/8503

(57) ABSTRACT

An HEMT includes a first III-V compound layer, a second III-V compound layer, and a III-V compound cap layer. The second III-V compound layer is disposed on the first III-V compound layer. The III-V compound cap layer covers and contacts the second III-V compound layer. The composition of the III-V compound cap layer and the second III-V compound layer are different from each other. A first opening is disposed in the III-V compound cap layer. A first insulating layer includes two first insulating parts and two second insulating parts. The two first insulating parts cover a top surface of the III-V compound cap layer, and the two second insulating parts respectively contact two sidewalls of the first opening. A second opening is disposed between the two first insulating parts and between the two second insulating parts. A gate electrode is disposed in the second opening.

### CROSS REFERENCE TO RELATED APPLICATIONS

This application is a division of U.S. application Ser. No. 17/885,574, filed on Aug. 11, 2022. The content of the application is incorporated herein by reference.

### BACKGROUND OF THE INVENTION

### 1. Field of the Invention

The present invention relates to a high electron mobility transistor (HEMT) and a method of fabricating the same, and more particularly to an HEMT with a structure which can prevent current leakage and a method of fabricating the same.

### 2. Description of the Prior Art

Due to their semiconductor characteristics, III-V semiconductor compounds may be applied in many kinds of integrated circuit devices, such as high power field effect transistors, high frequency transistors, or high electron mobility transistors. In the high electron mobility transistor, two semiconductor materials with different band-gaps are combined and a heterojunction is formed at the junction between the semiconductor materials as a channel for carriers. In recent years, gallium nitride based materials have been applied in high power and high frequency products because of their properties of wider band-gap and high saturation velocity.

A two-dimensional electron gas (2DEG) may be generated by the piezoelectric property of the GaN-based materials, and the switching velocity may be enhanced because of the higher electron velocity and the higher electron density of the 2DEG. However, numerous schottky diodes are formed around the bottom of the metal gate. Theses schottky diodes will lead to current leakage during the operation. Therefore, reliability and efficiency of the HEMT will be compromised.

### SUMMARY OF THE INVENTION

In view of this, an HEMT with an insulating layer disposed between a III-V compound cap layer and a gate electrode is provided to prevent current leakage.

According to a preferred embodiment of the present invention, an HEMT includes a first III-V compound layer. A second III-V compound layer is disposed on the first III-V compound layer, wherein composition of the first III-V compound layer and composition of the second III-V compound layer are different from each other. A III-V compound cap layer covers and contacts the second III-V compound layer, wherein composition of the III-V compound cap layer and composition of the second III-V compound layer are different from each other. A first opening is disposed within the III-V compound cap layer. A first insulating layer includes two first insulating parts and two second insulating parts, wherein the two first insulating parts cover a top surface of the III-V compound cap layer, and the two second insulating parts respectively contact two sidewalls of the first opening. A second opening is disposed between the two first insulating parts and between the two second insulating parts. A gate electrode is disposed in the second opening.

A fabricating method of an HEMT includes forming a first III-V compound layer, a second III-V compound layer and a III-V compound cap layer in sequence, wherein composition of the III-V compound cap layer and composition of the second III-V compound layer are different from each other. Next, a first opening is formed within the III-V compound cap layer. After that, an insulating layer is formed to cover the III-V compound cap layer and the insulating layer fills up the first opening. Subsequently, a second opening is formed within the insulating layer, wherein the second opening is disposed within the first opening. Finally, a gate electrode is formed within the second opening.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 5 depict a fabricating method of an HEMT according to a first preferred embodiment of the present invention, wherein:

FIG. 1 depicts a substrate covered by III-V compound layers;

FIG. 2 depicts a fabricating stage in continuous of FIG. 1;

FIG. 3 depicts a fabricating stage in continuous of FIG. 2;

FIG. 4 depicts a fabricating stage in continuous of FIG. 3;

FIG. 5 depicts a fabricating stage in continuous of FIG. 4.

FIG. 6 depicts a fabricating stage of forming a second opening according to another preferred embodiment of the present invention.

FIG. 7 depicts an HEMT according to an example of the present invention.

### DETAILED DESCRIPTION

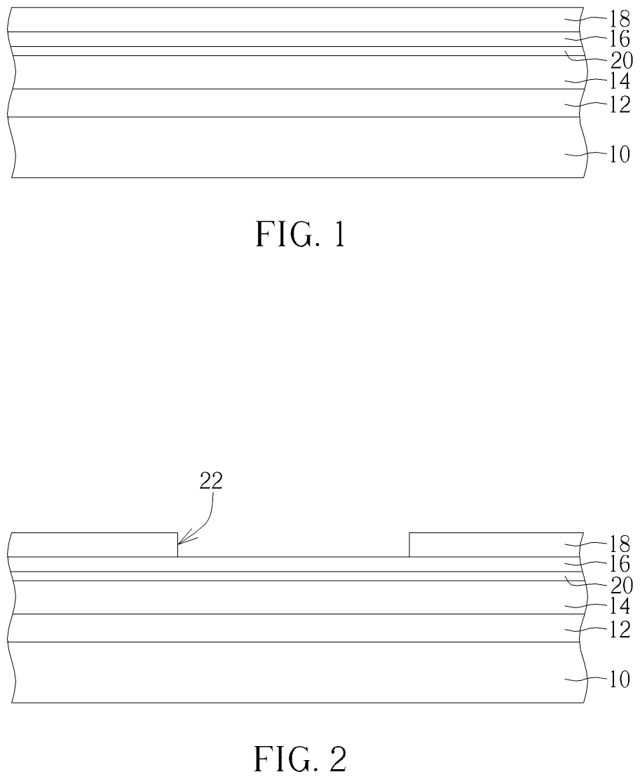

FIG. 1 to FIG. 5 depict a fabricating method of an HEMT according to a first preferred embodiment of the present invention.

As shown in FIG. 1, a substrate 10 is provided. Then, a buffer layer 12, a first III-V compound layer 14, a second III-V compound layer 16 and a III-V compound cap layer 18 are formed in sequence. The substrate 10 may be a bulk silicon substrate, a germanium substrate, a gallium arsenide substrate, a silicon germanium substrate, an indium phosphide substrate, a gallium nitride substrate, a silicon carbide substrate, or a silicon on insulator (SOI) substrate. The barrier layer 12 may include a nucleation layer, a transition layer and a superlattice. Composition of the barrier layer 12 may include aluminum nitride, aluminum gallium nitride or gallium nitride. The first III-V compound layer 14, the second III-V compound layer 16 and the III-V compound cap layer 18 can independently include gallium nitride, aluminum gallium nitride, aluminum indium nitride, aluminum indium gallium nitride, or aluminum nitride. Composition of the first III-V compound layer 14 and composition of the second III-V compound layer 16 are different from each other. Composition of the III-V compound cap layer 18 and composition of the second III-V compound layer 16 are also different from each other. According to a preferred embodiment of the present invention, the first III-V compound layer 14 is gallium nitride. The second III-V compound layer 16 is aluminum gallium nitride. The III-V compound cap layer 18 is gallium nitride. However, the first III-V compound layer 14, the second III-V compound layer 16 and the III-V compound cap layer 18 are not limited to above-mentioned material. Based on different product requirements, the first III-V compound layer 14, the second III-V compound layer 16 and the III-V compound cap layer 18 may be other kinds of III-V compounds.

Furthermore, an aluminum nitride layer 20 can be optionally disposed between the first III-V compound layer 14 and the second III-V compound layer 16. The first III-V compound layer 14 serves as a channel layer and the second III-V compound layer 16 serves as an active layer. The aluminum nitride layer 20 serves as a buffer layer between the first III-V compound layer 14 and the second III-V compound layer 16. Moreover, after the second III-V compound layer 16 is completed and before the substrate 10 leaves the chamber, the III-V compound cap layer 18 is formed on the second III-V compound layer 16 to protect the top surface of the second III-V compound layer 16 from been oxidized by air.

Next, as shown in FIG. 2, a first opening 22 is formed within the III-V compound cap layer 18. The first opening 22 preferably penetrates the III-V compound cap layer 18 to make the second III-V compound layer 16 exposed through the first opening 22. The first opening 22 can be formed by a lithographic process and an etching process.

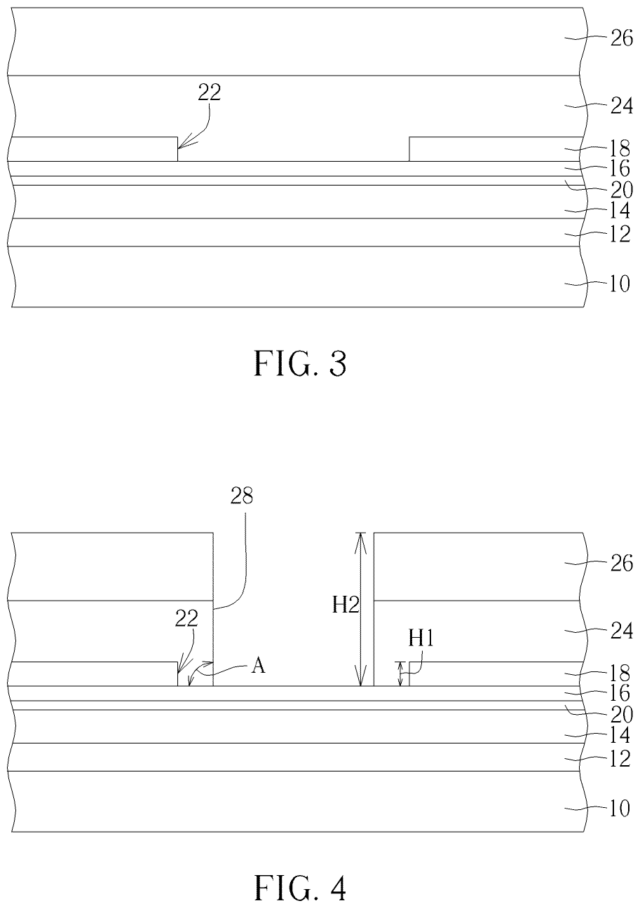

As shown in FIG. 3, a first insulating layer 24 is formed to cover the III-V compound cap layer 18 and the first insulating layer 24 fills up the first opening 22. According to another preferred embodiment, after the first insulating layer 24 is formed, a second insulating layer 26 can be formed optionally to cover the first insulating layer 24. This embodiment is exemplified as forming the second insulating layer 26. The first insulating layer 24 and the second insulating layer 26 are preferably silicon nitride. The first insulating layer 24 and the second insulating layer 26 can be formed by deposition processes. After the second insulating layer 26 is formed, a planarization process such as a chemical mechanical planarization is performed to planarize the top surface of the second insulating layer 26.

As shown in FIG. 4, a second opening 28 is formed within the second insulating layer 26 and the first insulating layer 24. A bottom of the second opening 28 is within the first opening 22. Furthermore, the second opening 28 does not contact the sidewalls of the first opening 22. A height H2 of the second opening 28 is greater than a height H1 of the first opening 22. The second opening 28 preferably penetrates the second insulating layer 26 and the first insulating layer 24 to make the second III-V compound layer 16 exposed from the second opening 28. The second opening 28 can be formed by a lithographic process and an etching process. An angle A is disposed between an outer sidewall of the second opening 28 and a top surface of the second III-V compound layer 16, and the angle A is preferably between 30 degrees and 90 degrees. In this embodiment, the angle A is shown as 90 degrees. According to another preferred embodiment in FIG. 6, the angle A can be smaller than 90 degrees but greater than 30 degrees.

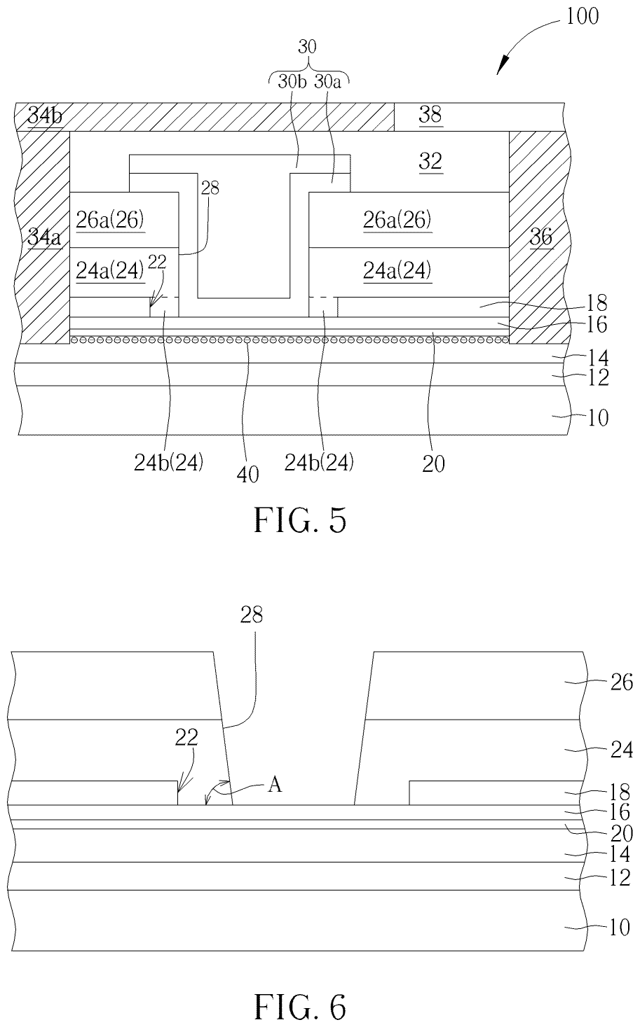

As shown in FIG. 5, a gate electrode 30 is formed within the second opening 28. In details, the steps of forming the gate electrode 30 includes forming a first metal layer 30a covering the second insulating layer 26 and covering conformally the second opening 28. Next, a second metal layer 30b is formed to cover the first metal layer 30a and fills in the second opening 28. Later, the first metal layer 30a and the second metal layer 30b are patterned to form the gate electrode 30. Subsequently, a dielectric layer 32 is formed to cover the second insulating layer 26 and the gate electrode 30. After that, a source electrode 34a and a drain electrode 36 are formed simultaneously. The source electrode 34a is at one side of the gate electrode 30, and the drain electrode 36 is at another side of the gate electrode 30. The source electrode 34a and a drain electrode 36 are respectively embedded within the dielectric layer 32, the second insulating layer 26, the first insulating layer 24, the III-V compound cap layer 18, the second III-V compound layer 16, the aluminum nitride layer 20 and the first III-V compound layer 14. After that, a dielectric layer 38 is formed to cover the dielectric layer 32. Next, a source extension 34b is formed to be embedded in the dielectric layer 38. The source extension 34b contacts the source electrode 34a. The source extension 34b is disposed on the gate electrode 30 and overlaps the gate electrode 30. The source extension 34b serves as a field plate. The source electrode 34a, the source extension 34b and the drain electrode 36 may include Au, Ti, W, Al, WN or other conductive materials. Now, an HEMT 100 of the present invention is completed.

As shown in FIG. 5, an HEMT 100 includes a first III-V compound layer 14. A second III-V compound layer 16 is disposed on the first III-V compound layer 14. The composition of the first III-V compound layer 14 and the composition of the second III-V compound layer 16 are different from each other. A III-V compound cap layer 18 covers and contacts the second III-V compound layer 16. The composition of the III-V compound cap layer 18 and composition of the second III-V compound layer 16 are different from each other. A first opening 22 is disposed within the III-V compound cap layer 18. A first insulating layer 24 covers the III-V compound cap layer 18. A second insulating layer 26 optionally covers the first insulating layer 24. The first insulating layer 24 includes two first insulating parts 24a and two second insulating parts 24b. The two first insulating parts 24a cover a top surface of the III-V compound cap layer 18, and the two second insulating parts 24b respectively contact two sidewalls of the first opening 22 and covers sidewalls of the III-V compound cap layer 18. The second insulating layer 26 includes two third insulating parts 26a. A second opening 28 is disposed between the two third insulating parts 26a, the two second insulating parts 24b and the two first insulating parts 24a. A gate electrode 30 is disposed in the second opening 28 and the gate electrode 30 covers the top surface of the second insulating layer 26. The gate electrode contacts the second III-V compound layer 16. A source electrode 34a is disposed at one side of the gate electrode 30 and embedded within the second insulating layer 26, the first insulating layer 24, the III-V compound cap layer 18, the second III-V compound layer 16, the aluminum nitride layer 20 and the first III-V compound layer 14. A source extension 34b is disposed on the source electrode 34a, and the source extension 34b contacts the source electrode 34a. The source extension 34b is disposed over the gate electrode 30. A drain electrode 36 is disposed at another side of the gate electrode 30 and embedded in within the second insulating layer 26, the first insulating layer 24, the III-V compound cap layer 18, the second III-V compound layer 16, the aluminum nitride layer 20 and the first III-V compound layer 14.

According to a preferred embodiment of the present invention, as shown in FIG. 4, an angle A is disposed between an outer sidewall of the second opening 28 and a top surface of the second III-V compound layer 16, and the angle A is preferably between 30 degrees and 90 degrees. The angle A is shown as 90 degrees in FIG. 4. However, according to another preferred embodiment in FIG. 6, the angle A can be smaller than 90 degrees but greater than 30 degrees. Please refer to FIG. 5 again. It is noteworthy that the first insulating layer 24 separates the gate electrode 30 and the III-V compound cap layer 18; therefore the gate electrode 30 and the III-V compound cap layer 18 do not contact each other. Furthermore, the III-V compound cap layer 18 includes gallium nitride, aluminum nitride or indium gallium nitride, wherein the gallium nitride can be undoped gallium nitride, N-type gallium nitride (such as carbon-doped gallium nitride) or P-type gallium nitride (such as magnesium-doped gallium nitride), but not limited to those materials. According to a preferred embodiment, the III-V compound cap layer 18 is gallium nitride. A thickness of the III-V compound cap layer 18 is exemplified as between 1 and 5 nm in this embodiment. The III-V compound cap layer 18 is exemplified as gallium nitride. Moreover, the second insulating layer 26 and the first insulating layer 24 include silicon nitride, silicon oxide or silicon oxynitride. In this embodiment, the second insulating layer 26 and the first insulating layer 24 are preferably silicon nitride. The HEMT 100 is a normally-on transistor. Two dimensional electron gas 40 is generated in the first III-V compound layer 14 which serves as a channel layer.

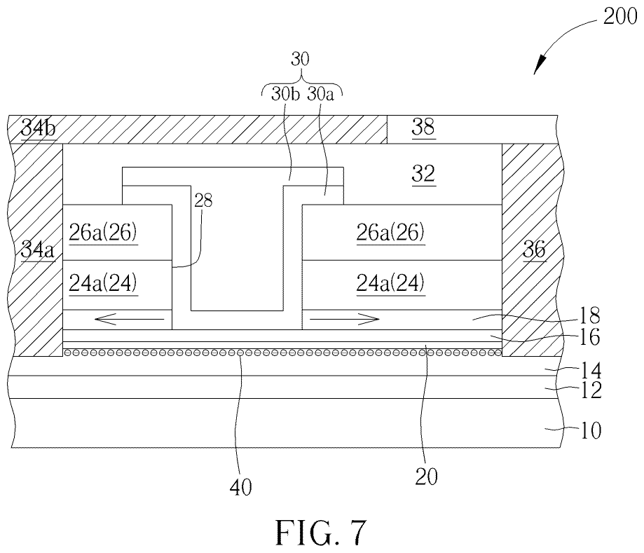

FIG. 7 depicts an HEMT according to an example of the present invention, wherein elements which are substantially the same as those in the embodiment of FIG. 5 are denoted by the same reference numerals; an accompanying explanation is therefore omitted.

The difference between the HEMT 200 in FIG. 7 and the HEMT 100 in FIG. 5 is that the III-V compound cap layer 18 of the HEMT 200 contacts the gate electrode 30. On the other hand, the III-V compound cap layer 18 of the HEMT 100 does not contact the gate electrode 30 because there is the first insulating layer 24 disposed between the III-V compound cap layer 18 and the gate electrode 30. In the HEMT 200, a schottky diode is formed at an interface between the gate electrode 30 and the III-V compound cap layer 18 because III-V compound cap layer 18 contacts the gate electrode 30. The schottky diode has low reverse bias; therefore leakage current (shown by arrows) will be easily formed at the interface between the gate electrode 30 and the III-V compound cap layer 18. However, in the HEMT 100, the first insulating layer 24 is disposed between the III-V compound cap layer 18 and the gate electrode 30 to block the formation of the schottky diode. In this way, the current leakage can be prevented.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A fabricating method of a high electron mobility transistor (HEMT), comprising:
forming a first III-V compound layer, a second III-V compound layer and a III-V compound cap layer in sequence, wherein composition of the III-V compound cap layer and composition of the second III-V compound layer are different from each other;
forming a first opening within the III-V compound cap layer;
forming an insulating layer covering the III-V compound cap layer and the insulating layer filling up the first opening;
forming a second opening within the insulating layer, wherein the second opening is disposed within the first opening; and
forming a gate electrode within the second opening.

2. The fabricating method of an HEMT of claim 1, further comprising:
forming a source electrode and a drain electrode respectively embedded within the insulating layer, the III-V compound cap layer, the second III-V compound layer and the first III-V compound layer, wherein the source electrode is disposed at one side of the gate electrode, and the drain electrode is disposed at another side of the gate electrode.

3. The fabricating method of an HEMT of claim 1, wherein the second III-V compound layer is exposed from the second opening.

4. The fabricating method of an HEMT of claim 1, wherein the III-V compound cap layer contacts the second III-V compound layer.

5. The fabricating method of an HEMT of claim 1, wherein composition of the first III-V compound layer and composition of the second III-V compound layer are different from each other.

6. The fabricating method of an HEMT of claim 1, wherein the gate electrode does not contact the III-V compound cap layer.

7. The fabricating method of an HEMT of claim 1, wherein the III-V compound cap layer comprises gallium nitride, aluminum nitride or indium gallium nitride.
